(19) United States
(12) Patent Application Publication
(10) Pub. No.: US 2009/0156011 A1
(43) Pub. Date: Jun. 18, 2009

(54) Method of controlling CD bias and CD microloading by changing the ceiling-to-wafer gap in a plasma reactor

(76) Inventors: Rodolfo P. Belen, (US); Edward P. Hammond, IV, (US); Dan Katz, (US); Valentin N. Todorow, (US); Brian K. Hatcher, (US); Alexander M. Paterson, (US)

Correspondence Address: LAW OFFICE OF ROBERT M. WALLACE, 2112 EASTMAN AVENUE, SUITE 102, VENTURA, CA, 93003, US

(21) Appl. No.: 12/001,986

(22) Filed: Dec. 12, 2007

(51) Int. Cl. H01L 21/3065

(52) U.S. Cl. 438/710; 257/E21.218

(57) ABSTRACT

In a plasma etch process, critical dimension (CD), CD bias and CD bias microloading are controlled independently of plasma process conditions or parameters, such as RF power levels, pressure and gas flow rate, by depressing or elevating the workpiece support pedestal to vary the gap between the workpiece and the chamber ceiling facing the workpiece, using an axially adjustable workpiece support.

### BACKGROUND

In plasma processing of semiconductor wafers, precise feature profile control has become increasingly important during gate etching as the critical dimensions of semiconductor devices continue to scale down below 45 nm. For example, the integrity and critical dimension (CD) control of the hardmask during gate mask definition is critical in gate etch applications. For example, for a polysilicon gate, the hardmask layer overlying the polysilicon layer is silicon nitride. For etching (definition) of the silicon nitride hardmask layer, the CD of greatest criticality is the mask length at the bottom of the hardmask. Likewise, for etching of the polysilicon gate, the CD of greatest criticality is the gate length at the bottom of the polysilicon gate. This length typically defines the all-important channel length of the transistor during later process steps. Therefore, during definition (etching) of the hardmask or of the polysilicon gate, it is important to minimize discrepancy between the required CD and the CD obtained at the end of the etch step. It is also important to minimize the CD bias, the difference between the CD as defined by the mask and the final CD after the etch process. Finally, it is important to minimize the CD bias microloading, which is the difference between the CD bias in regions in which the discrete circuit features are dense or closely spaced and the CD bias in regions in which the discrete circuit features are isolated or widely spaced apart.

Various conventional techniques have been used to meet these requirements. For instance, trial-and-error techniques have been used for determining the optimum gas flow rates for the various gas species in the reactor, the optimum ion energy (determined mainly by RF bias power on the wafer) and the optimum ion density (determined mainly by RF source power on the coil antenna). The foregoing process parameters affect not only CD, CD bias and CD bias microloading but also affect other performance parameters, such as etch rate and etch rate uniformity. It may not be possible to set the process parameters to meet the required performance parameters such as etch rate and at the same time obtain optimize CD and minimize CD bias and CD bias microloading. As a result, the process window, e.g., the allowable ranges of process parameters such as chamber pressure, gas flow rates, ion energy and ion density, may be unduly narrow to satisfy all requirements.

### SUMMARY

A method is provided for performing a plasma etch process on a production workpiece in a reactor chamber having a ceiling overlying a workpiece support surface. The method comprises providing an adjustable workpiece-to-ceiling gap between the workpiece support surface and the ceiling. The method begins by performing successive plasma etch processes on successive test workpieces under identical process conditions at different successive values of the gap.

In accordance with a first embodiment, the method further comprises measuring a critical dimension (CD) bias as a pre-etch to post-etch change in a critical dimension (CD) for isolated features and for dense features on each of the test workpieces and correlating each CD bias with the corresponding workpiece-to-ceiling gap to produce correlated measurements. The method additionally comprises searching the correlated measurements for: (1) a first value of the gap at which CD bias of the isolated features exceeds that of the dense features, and (2) a second value of the gap at which CD bias of the dense features exceeds that of the isolated features. The method further comprises placing the production workpiece in the reactor, setting the gap to an intermediate value lying between the first and second gap values and performing an etch process while maintaining the process parameters at the same set of corresponding parameter values.

In accordance with a second embodiment, the etch processing of the successive test workpieces is followed by measuring a critical dimension (CD) bias as a pre-etch to post-etch change in a critical dimension (CD) and correlating each CD bias with the corresponding workpiece-to-ceiling gap to produce correlated measurements. In this second embodiment, the method further comprises searching the correlated measurements for an optimum value of the gap at which CD bias is less than a predetermined value of CD bias. The method further comprises placing the production workpiece in the reactor, setting the gap to the optimum value and performing an etch process while maintaining the process parameters at the same set of corresponding parameter values.

In accordance with a third embodiment, the etch processing of the successive test workpieces is followed by measuring a post-etch critical dimension (CD) on each test workpiece and correlating each CD with the corresponding workpiece-to-ceiling gap to produce correlated measurements. In this third embodiment, the method further comprises searching the correlated measurements for: (1) a first value of the gap at which measured CD features exceeds a desired CD value, and (2) a second value of the gap at which measured CD is less than the desired CD value. The method of the third embodiment further comprises placing the production workpiece in the reactor, setting the gap to an intermediate value between the first and second values and performing an etch process while maintaining the process parameters at the same set of corresponding parameter values.

### BRIEF DESCRIPTION OF THE DRAWINGS

So that the manner in which the above recited embodiments of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1A depicts a thin film structure on a semiconductor wafer prior to polysilicon gate hardmask etch.

FIG. 1B depicts the thin film structure corresponding to FIG. 1A after hardmask etching.

FIG. 1C depicts passivation of etched feature sidewalls.

FIG. 2 illustrates a plasma reactor adapted to carry out a process of one embodiment.

FIG. 3A depicts the position of the pedestal in the reactor of FIG. 2 at a small gap size.

FIG. 3B depicts the gate etch profile obtained at the gap size of FIG. 3A.

FIG. 4A depicts the position of the pedestal in the reactor of FIG. 2 at an intermediate gap size.

FIG. 4B depicts the gate etch profile obtained at the gap size of FIG. 4A.

FIG. 5A depicts the position of the pedestal in the reactor of FIG. 2 at a large gap size.

FIG. 5B depicts the gate etch profile obtained at the gap size of FIG. 5A.

FIG. 6 is a graph depicting etch rate as a function of gap size.

FIGS. 7A, 7B, 7C and 7D provide comparisons of etch profiles and CD for different gap sizes for dense and isolated features, of which:

FIG. 7A depicts etch profile of an isolated feature at a small gap size.

FIG. 7B depicts etch profile of feature in a dense region at a small gap size.

FIG. 7C depicts etch profile of an isolated feature at a large gap size.

FIG. 7D depicts etch profile of a feature in a dense region at a large gap size.

FIG. 8 is a graph having an ordinate representing CD bias in nm and an abscissa representing radial position on the wafer for an etch process using a narrow gap size for isolated features (diamond symbols) and dense features (square symbols).

FIG. 9 is a graph having an ordinate representing CD bias in nm and an abscissa representing radial position on the wafer for an etch process using a large gap size for isolated features (diamond symbols) and dense features (square symbols).

FIG. 10 is a graph having an ordinate representing CD bias in nm and an abscissa representing radial position on the wafer for an etch process using an intermediate gap size for isolated features (diamond symbols) and dense features (square symbols).

FIGS. 11A, 11B, 11C, 11D and 11E are respective graphs depicting, respectively, bias voltage, ion density, critical dimension, CD bias and CD bias microloading, as functions of the wafer-to-ceiling gap size.

FIG. 12 is a block diagram depicting an etch process in accordance with an embodiment.

To facilitate understanding, identical reference numerals have been used, where possible, to designate identical elements that are common to the figures. The drawings in the figures are all schematic and not to scale.

### DETAILED DESCRIPTION

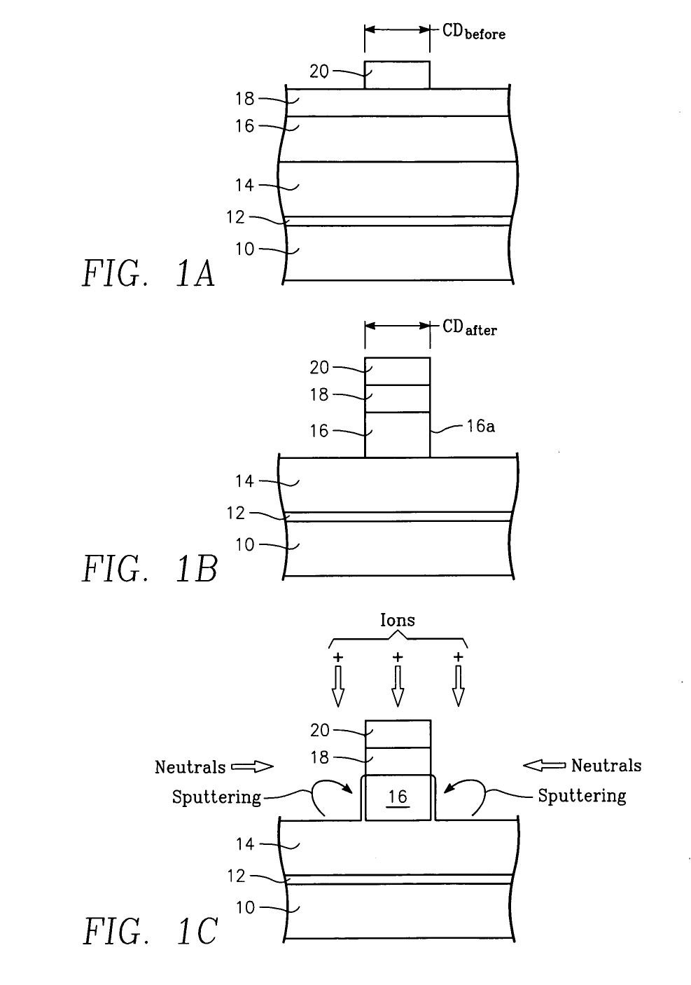

FIG. 1A depicts a thin film structure that is formed during fabrication of a field effect transistor. The structure includes a semiconducting crystalline silicon layer or substrate 10, a thin gate oxide layer 12, a polysilicon gate layer 14 on the gate oxide layer 12, a silicon nitride hardmask layer 16 overlying the polysilicon gate layer, a conventional anti-reflection coating 18 overlying the hardmask layer 16 and a photoresist layer 20 overlying the anti-reflection coating 18. The photoresist layer 20 has been photolithographically defined in a pattern having features defining a critical dimension, CD, such as a gate length. The CD of the photoresist mask, prior to plasma etching, is depicted in FIG. 1A, and is labeled CD_{before}. The silicon nitride hardmask layer 16 is etched to remove portions except those protected by the photoresist mask 20 to form the structure of FIG. 1B. The dimension of interest is the CD at the bottom of the hardmask, this dimension being labeled CD_{after} in FIG. 1B. Any difference between CD_{before} and CD_{after} is defined as the CD bias: CD_{bias}=CD_{before}−CD_{after}. It is desired to minimize CD_{bias}. The CD bias can be a large negative value if the CD decreases greatly during the etch process. This may happen, for example, if there is insufficient passivation of the hardmask side wall 16a (FIG. 1B) during etching of the hardmask 16. The side wall 16a is passivated by deposition of polymers formed in the plasma and by re-deposition of material sputtered from the exposed surfaces of the hardmask layer 16 or other layers, as indicated in FIG. 1C. Bombardment by plasma ions prevents passivation of the horizontal surfaces due to the predominantly vertical direction of the ion velocity profile.

Another problem is that the CD bias in regions of the integrated circuit in which the features are dense (closely spaced) is different from the CD bias in regions in which the features are more isolated. As understood in this description, isolated features are those features whose nearest neighbor is more than 300 nm away, while dense features are those features whose nearest neighbors are within less than 100 nm. The spacing of vertical features affects the flux of laterally moving neutral species that tend to deposit on and passivate the side walls (e.g., the hardmask side wall 16a). Such a difference is the CD bias microloading, and is defined as the difference between the CD bias in dense regions, CD_{bias}(dense) and the CD bias in isolated regions, CD_{bias}(isolated):

CD bias microloading=CD_{bias}(dense)−CD_{bias}(isolated)

Controlling CD bias and CD bias microloading requires controlling gas flow rates, chamber pressure, plasma ion density, plasma ion energy, etc., which narrows the useful range of such features. What is needed is a way of controlling CD, CD bias and CD bias microloading that without necessarily affecting gas flow rate, chamber pressure and plasma ion density and energy.

In one embodiment, the CD bias microloading is minimized or eliminated by adjusting the gap between the wafer and the chamber ceiling without having to change other processing parameters (e.g., chamber pressure, gas flow rates, plasma ion density or plasma ion energy). In another embodiment, this gap is adjustable to control the CD bias as well as the CD itself without changing the other processing parameters.

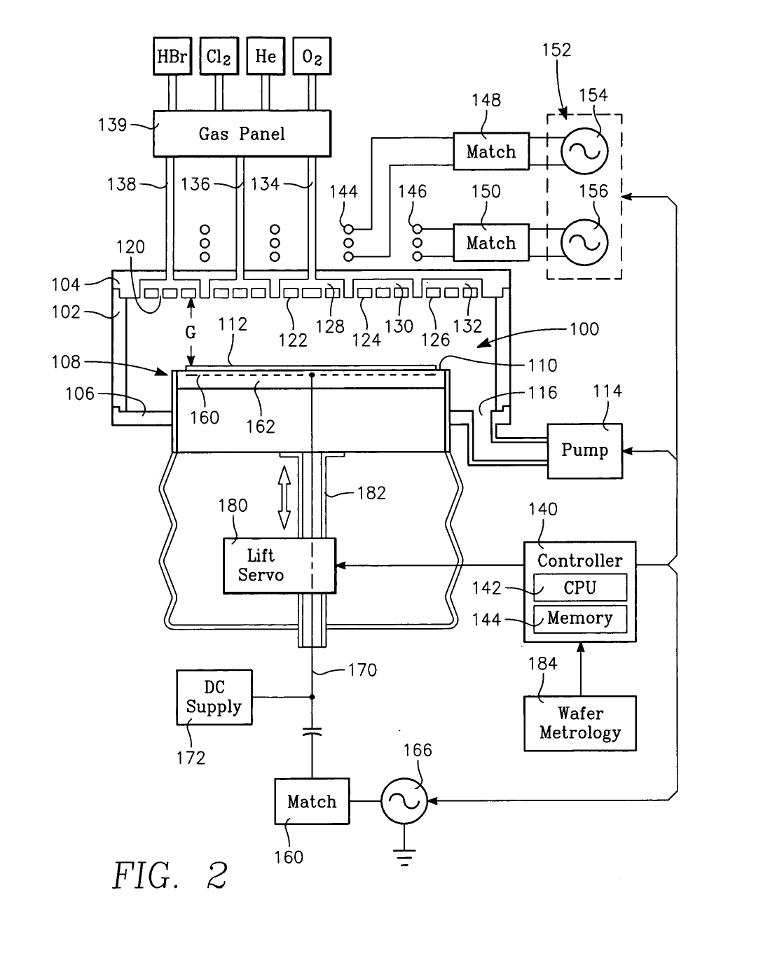

FIG. 2 illustrates an exemplary plasma reactor adapted to process a wafer or workpiece while controlling CD bias microloading, CD bias or the CD itself by adjusting the wafer-to-ceiling gap. The reactor has a chamber 100 enclosed by a cylindrical side wall 102, a ceiling 104 and a floor 106. A wafer support pedestal 108 has a wafer support surface 110 facing the ceiling 104 for supporting a workpiece 112 such as a semiconductor wafer. The pedestal 108 and the side wall 102 define a pumping annulus through which the chamber 100 is evacuated by a vacuum pump 114 through a pumping port 116 in the floor 106. The ceiling 104 is the bottom surface of a gas distribution plate 118 having an array of gas injection orifices 120. The orifices 120 are divided into three separate concentric groups or gas injection zones, including an inner zone 122, an intermediate zone 124 and an outer zone 126. The gas distribution plate further includes respective internal gas manifolds 128, 130, 132 supplying process gas to the gas injection zones 122, 124, 126, respectively. The manifolds 128, 130, 132 are connected to respective gas panel outlets 134, 136, 138. A gas panel 139 can be controlled to supply different process gases or gas mixtures to the different outlets 134, 136, 138 at different gas flow rates determined by a programmable controller 140 of a conventional type that may include a central processing unit 142 and a memory 144.

RF plasma source power is coupled into the chamber 100 by inner and outer concentric coil antennas 144, 146 coupled through RF impedance match circuits 148, 150 to a common RF power source 152 which may consist of individually controllable RF power outputs 154, 156. The separate outputs may be derived from a single RF generator or, as depicted in FIG. 2, may be implemented as separate RF power generators. RF plasma bias power is coupled to the wafer 112 by an electrode 160 provided in the pedestal 108 underneath the wafer support surface 110. The electrode 160 is separated from the wafer support surface 110 by a thin portion of an insulating layer 162 within which the electrode 160 is formed. An RF plasma bias power generator 166 is coupled to the electrode 160 through an RF impedance match circuit 168 connected to the electrode 160 via an insulated conductor 170. A D.C. chucking voltage supply 172 may be connected to the conductor 170 for application of an electrostatic chucking voltage to electrostatically clamp the wafer 112 to the wafer support surface 110.

The pedestal 108 is movable in the axial direction relative to the chamber 100 by an elevation actuator 180. The pedestal 108 extends through the floor 106 and is supported on an elevator shaft 182 that is mechanically coupled to the elevation actuator 180 by conventional mechanical linkage that enables the actuator 180 to move the shaft up or down in the axial direction so as to control a variable gap “G” between the wafer 112 and the ceiling 104. The controller 140 governs the actuator 180. The gap can be varied from 2 inches to 6 inches. A separate wafer metrology apparatus 184 may be employed for measuring dimensions of features in a thin film structure on a wafer either before or after processing of the wafer in the chamber 100. The dimension measured may be the critical dimension (e.g., defining gate length) of a hardmask layer or of a polysilicon gate layer.

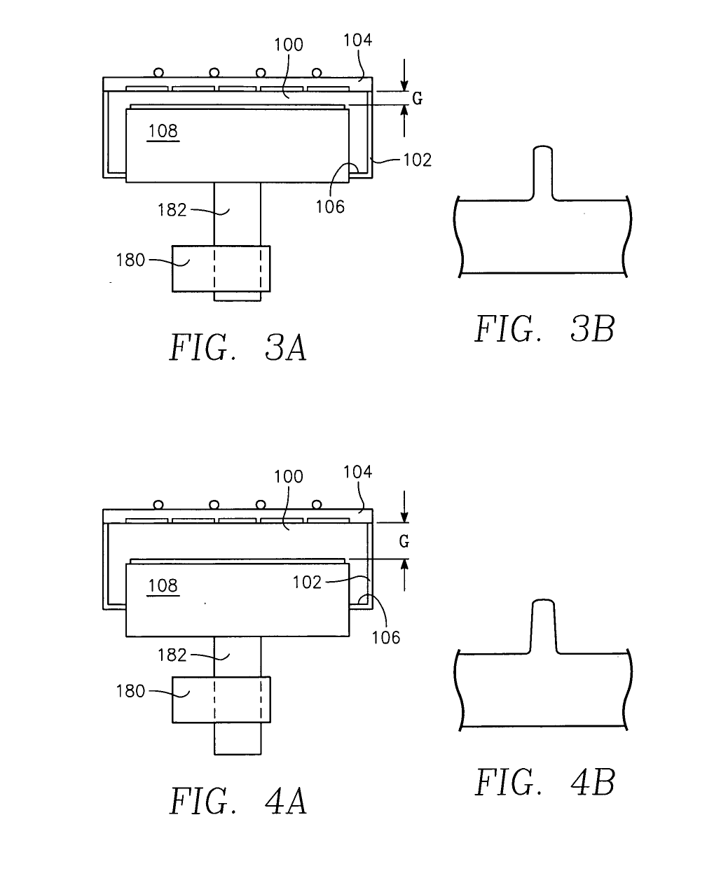

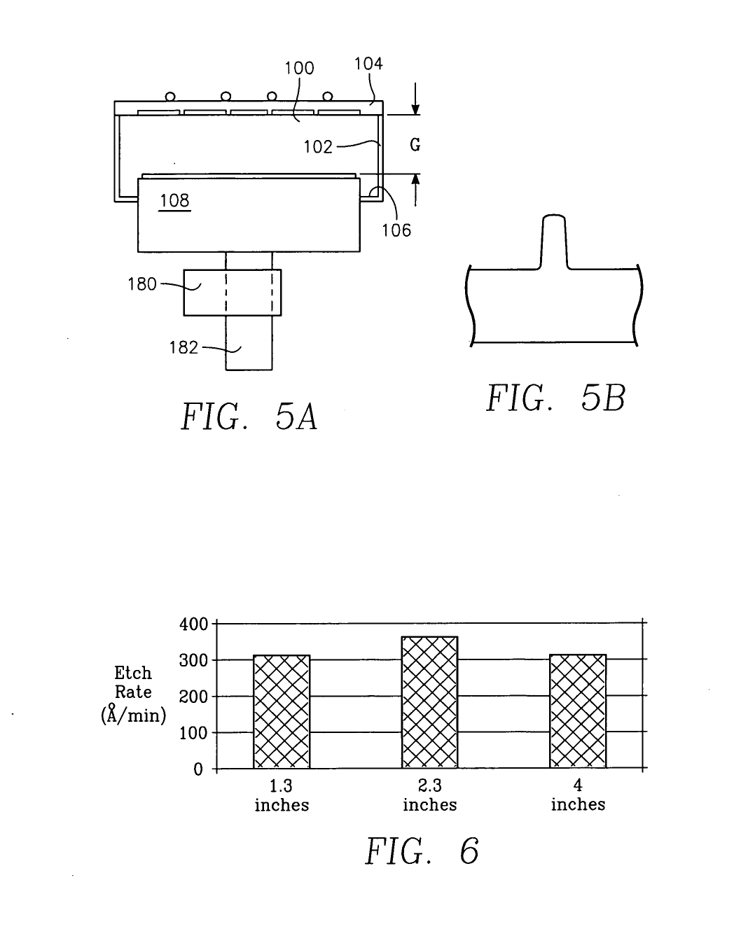

FIGS. 3A, 4A and 5A are simplified views of the reactor of FIG. 2 depicting the pedestal 108 at different respective positions at which the gap G is at three successive values. While not limiting the disclosure to specific values, in the particular example depicted, the values of G are, respectively, 1.3 inches, 2.3 inches as 4 inches. FIGS. 3B, 4B and 5B depict contours of the structure of FIG. 1B, after the etch process, showing the increase in the etched feature size as the gap G is increased from 1.3 inches (FIG. 3B) to 2.3 inches (FIG. 4B) to 4 inches (FIG. 5B). FIG. 6 is a graph depicting the etch rate as a function of the gap G in the three examples of FIGS. 3A, 4A and 5A. In the etch process of this example, a silicon nitride hardmask is etched in a plasma from an etchant species precursor gas, CF₄ and a passivation species precursor gas, CHF₃. FIG. 6 shows that the etch rate is at a maximum at the intermediate gap value of 2.3 inches but falls off if the gap is either increased or decreased. This is due to opposing trends in ion density and ion energy with electrode spacing. Specifically, as the gap G increases, the ion energy increases but density decreases. Conversely, as the gap G decreases, the ion density increases while ion energy decreases. At the intermediate gap value of 2.3 inches, the combined effect of the ion density and ion energy is at an optimum point at which the etch rate is greatest.

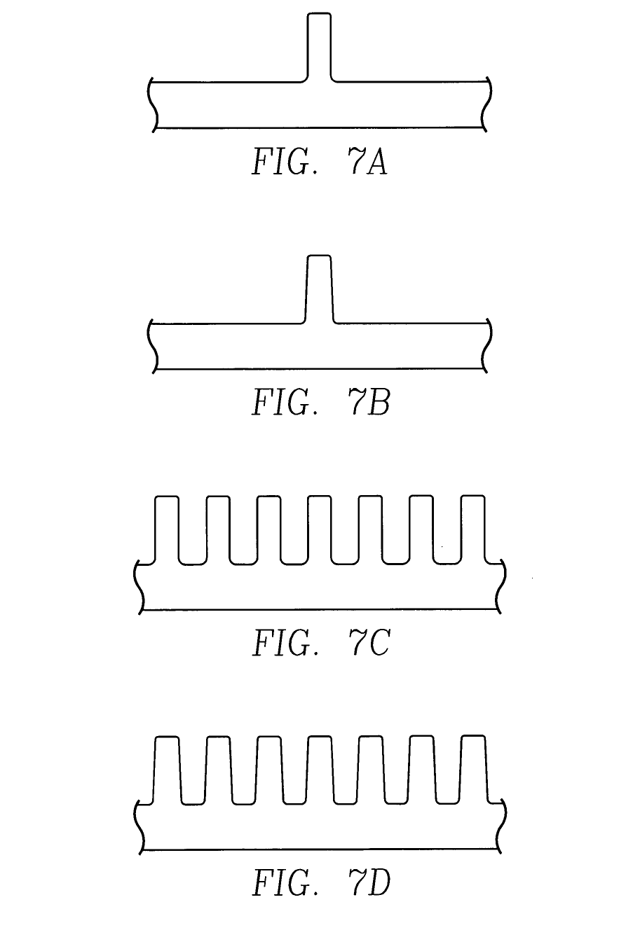

FIGS. 7A-7D represent an aspect of certain embodiments where the wafer-ceiling gap is used to manipulate CD bias microloading without having to change other process parameters. FIGS. 7A-7D compare differences between CD's of isolated and dense features at two different gap widths. FIGS. 7A and 7B compare the CD's of an etched hardmask feature at a small gap G of 2.3 inches for isolated features and dense features. The dense features (FIG. 7B) have a slightly greater CD than the isolated features (FIG. 7A). FIGS. 7C and 7D compare the CD's of etched hardmask features at a large gap G of 5 inches for isolated and dense features. The isolated features (FIG. 7C) have a slightly greater CD than the dense features (FIG. 7D).

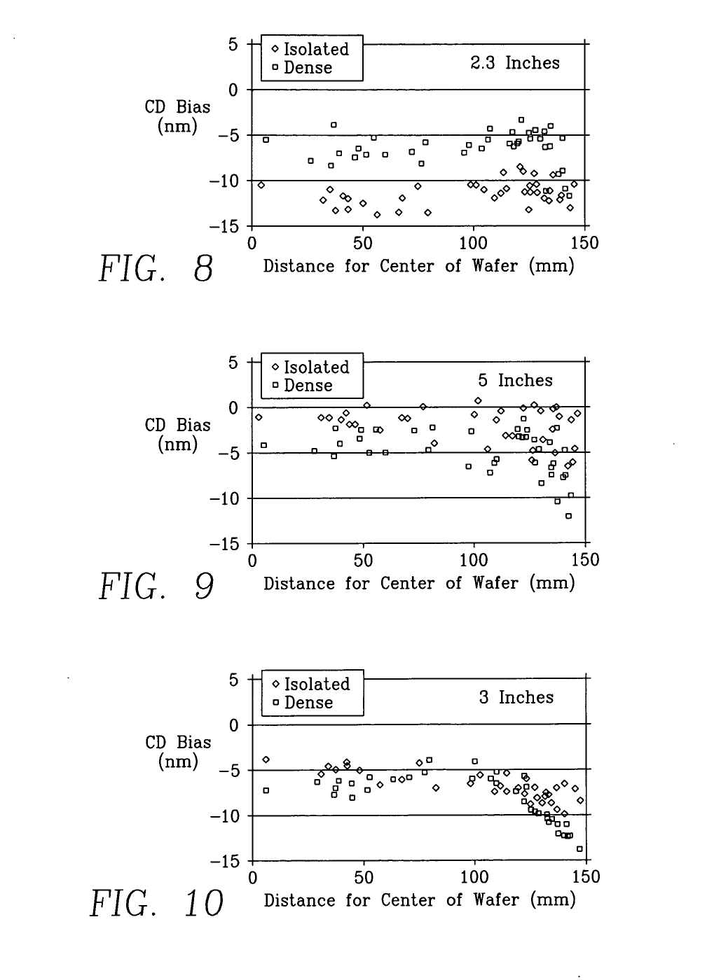

These results are summarized in the graphs of FIGS. 8 and 9, each of which depicts CD bias as a function of radial position for two groups of features, namely dense features (square symbols) and isolated features (diamond symbols). In FIG. 8, the gap G is small (2.3 inches) and the isolated features (diamonds) have a larger CD bias than the dense features (squares). In FIG. 9, the gap is large (5 inches) and the case is just the reverse from FIG. 8: the dense features (squares) have a larger CD bias than the isolated features (diamonds). Thus, by moving the pedestal up and down between large and small gap values, the CD bias of the isolated features is shifted either above or below the CD bias of the dense features. In one embodiment, an intermediate value of the gap G lying between the extremes of FIGS. 8 and 9 at which the CD bias values of the dense and isolated features are the same is determined. The intermediate value of the gap G provides even greater uniformity and control of CD. This optimum state is depicted in the results of the graph of FIG. 10, in which the gap G is at the intermediate value of 3 inches. In FIG. 10, the distribution of CD bias values of dense features (square symbols) and isolated features (diamond symbol) essentially merge, so that the CD bias microloading is essentially zero at the intermediate gap. Thus, we have discovered that the variable wafer-ceiling gap can be set to a value established between two extremes at which the CD bias microloading is zero or nearly zero.

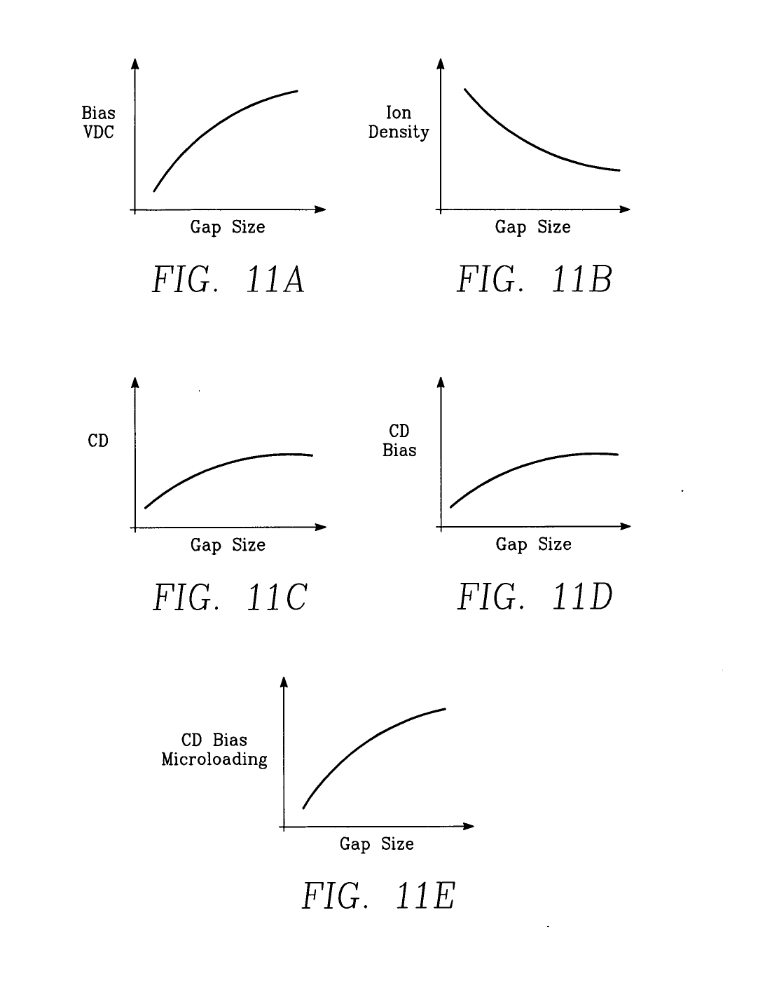

FIGS. 11A-11E summarize the effects of the movable pedestal and variable gap that provide the foregoing results. FIG. 11A is a graph showing how the bias voltage increases with the gap size. FIG. 11B is a graph showing that the ion density decreases with the gap size. FIG. 11C is a graph showing that the CD (e.g., gate length) increases with the gap size. FIG. 11D is a graph showing that the CD bias increases with the gap size. FIG. 11E is a graph showing that the CD bias microloading goes from a negative to a positive value as the gap size increases. This shows that in one embodiment, CD bias microloading can be varied within a range of values between a positive value and a negative value, including zero. In some applications, the gap size may be selected to obtain a non-zero value of CD bias microloading, while in other applications the gap size may be selected to obtain zero CD bias microloading.

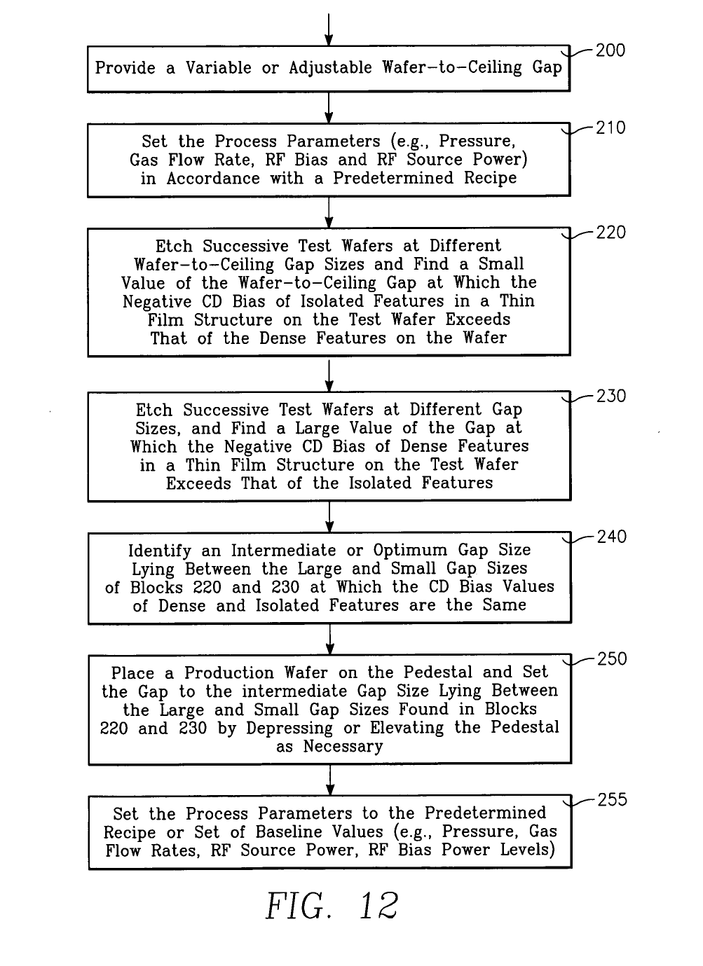

FIG. 12 is a flow diagram depicting a process in accordance with one embodiment for processing a wafer with a more uniform distribution of CD by essentially eliminating CD bias microloading. The process employs a reactor like that of FIG. 2 that provides a variable or adjustable wafer-to-ceiling gap (block 200 of FIG. 12). The process parameters (e.g., chamber pressure, gas flow rate, RF bias power, RF source power) are set in accordance with a predetermined recipe (block 210). Successive test wafers are etched at different wafer-to-ceiling gap sizes; the CD bias is measured for each etching; and, a small value of the wafer-to-ceiling gap G is found at which the negative CD bias of isolated features in a thin film structure on the test wafer exceeds that of the dense features on the wafer (block 220). Using a similar approach by etching successive test wafers at different gap sizes, the CD bias is measured for each, and a large value of the gap G is found at which the negative CD bias of dense features in a thin film structure on the test wafer exceeds that of the isolated features (block 230). An intermediate gap size lying between the large and small gap sizes of blocks 220 and 230 is identified at which the CD bias values of dense and isolated features are the same (block 240). Finally, a production wafer is etched under the same process conditions using the intermediate gap size lying between the large and small gap sizes found in the steps of blocks 220 and 230. The intermediate gap size is identified as one at which CD bias is the same for both dense and isolated features. An example of such an optimum gap size is the gap G of 3 inches that produced the results of FIG. 10.

The etch process is carried out by placing a production wafer on the pedestal 108 and setting the gap size to the intermediate or optimum value identified in block 240 by elevating or depressing the variable height pedestal 108 as necessary (block 250). In block 255, the process parameters are set to the predetermined recipe or set of baseline values (e.g., chamber pressure, gas flow rates, RF source power level, RF bias power level) to carry out the etch process.

In the process of FIG. 12, an intermediate gap size G was sought between two values at which the CD bias microloading was, respectively, positive and negative. In accordance with another embodiment, the process of FIG. 12 is modified to determine two values of the gap G at which the measured CD is less than and greater than, respectively, a desired CD value. In this embodiment, the measurement steps of blocks 220 and 230 are modified to measure CD rather than CD bias. The two gap sizes identified in this modified version of blocks 220 and 230 are ones at which the CD is, respectively, less than and greater than a desired CD value. The intermediate value to which the gap is set for etching the production wafer is one at which the CD is closer to (or equals) the desired CD value.

In yet another modification of the process of FIG. 12, only the CD bias is measured (e.g., in block 220), and the gap G is adjusted to minimize the CD bias below a predetermined threshold.

In summary, the variable height pedestal 108 may be used to adjust the wafer-to-ceiling gap G to control the overall CD of an etched feature without requiring a change of any other process parameters such as chamber pressure, gas flow rates, RF source power level or RF bias power level. The variable height pedestal 108 may be used to adjust the CD bias of an etched feature, e.g., the difference between the CD of the mask prior to the etch step and the bottom CD of the etched feature at the conclusion of the etch step. Finally, the variable height pedestal 108 may be used to adjust the CD bias microloading, e.g., the difference between the CD bias in areas on the wafer of dense structural features and the CD bias in areas on the wafer of isolated structural features. A required result in CD, CD bias or CD bias microloading may be obtained using the variable gap feature, while the other process parameters (pressure, flow rate, RF power levels) may be varied as desired to satisfy other process requirements (e.g., etch rate, ion energy level, etc.). As a result, the overall process window or allowable range of process parameter values is greatly increased.

While the foregoing is directed to embodiments of the invention, other and further embodiments of the invention may be devised without departing from the basic scope thereof, and the scope thereof is determined by the claims that follow.

What is claimed is:

1. A method for performing a plasma etch process on a production workpiece in a reactor chamber having a ceiling overlying a workpiece support surface, comprising:
providing an adjustable workpiece-to-ceiling gap between said workpiece support surface and said ceiling;
performing successive plasma etch processes on successive test workpieces under identical process conditions at different successive values of said gap;
measuring a critical dimension (CD) bias as a pre-etch to post-etch change in a critical dimension (CD) for isolated features and for dense features on each of said test workpieces and correlating each CD bias with the corresponding workpiece-to-ceiling gap to produce correlated measurements;
searching said correlated measurements for: (1) a first value of said gap at which CD bias of the isolated features exceeds that of the dense features, and (2) a second value of said gap at which CD bias of the dense features exceeds that of the isolated features; and
placing the production workpiece in said reactor, setting said gap to an intermediate value lying between said first and second gap values and performing an etch process while maintaining said process parameters at said same set of corresponding parameter values.

2. The method of claim 1 wherein said intermediate value of said gap is one at which the CD bias values of dense and isolated features are closer to one another than at said first and second values of said gap.

3. The method of claim 1 wherein said intermediate value of said gap is one at which the CD bias values of dense and isolated features are at least nearly the same.

4. The method of claim 1 wherein said first value of said gap is less than said second value of said gap.

5. The method of claim 1 wherein each of said successive etch processes comprises:
flowing a process gas into said chamber at a gas flow rate;
evacuating said chamber to a chamber pressure;
coupling RF bias power to the workpiece at a bias power level;
coupling RF source power into the chamber at a source power level.

6. The method of claim 5 wherein said process conditions comprise said gas flow rate, said chamber pressure, said bias power level and said source power level, wherein said gas flow rate, said chamber pressure, said bias power level and said source power level are the same for each of said successive etch processes.

7. The method of claim 6 wherein said process conditions provide a required process performance value.

8. The method of claim 7 wherein said required performance value is a desired etch rate.

9. The method of claim 1 wherein measuring a critical dimension (CD) bias as a pre-etch to post-etch change in a critical dimension (CD) for isolated features and for dense features on each of said test workpieces comprises measuring said CD bias in regions of the test workpiece having isolated features and measuring said CD bias in regions of the test workpiece having dense features.

10. The method of claim 9 said measuring further comprises distinguishing features separated by less than 100 nm as dense features and distinguishing features separated by more than 300 nm as isolated features.

11. A method for performing a plasma etch process on a production workpiece in a reactor chamber having a ceiling overlying a workpiece support surface, comprising:
providing an adjustable workpiece-to-ceiling gap between said workpiece support surface and said ceiling;
performing successive plasma etch processes on successive test workpieces under identical process conditions at different successive values of said gap;
measuring a critical dimension (CD) bias as a pre-etch to post-etch change in a critical dimension (CD) and correlating each CD bias with the corresponding workpiece-to-ceiling gap to produce correlated measurements;
searching said correlated measurements for an optimum value of said gap at which CD bias is less than a predetermined value of CD bias; and
placing the production workpiece in said reactor, setting said gap to said optimum value and performing an etch process while maintaining said process parameters at said same set of corresponding parameter values.

12. The method of claim 11 wherein each of said successive etch processes comprises:
flowing a process gas into said chamber at a gas flow rate;
evacuating said chamber to a chamber pressure;
coupling RF bias power to the workpiece at a bias power level;
coupling RF source power into the chamber at a source power level.

13. The method of claim 12 wherein said process conditions comprise said gas flow rate, said chamber pressure, said bias power level and said source power level, wherein said gas flow rate, said chamber pressure, said bias power level and said source power level are the same for each of said successive etch processes.

14. The method of claim 13 wherein said process conditions provide a required process performance value.

15. The method of claim 14 wherein said required performance value is a desired etch rate.

16. A method for performing a plasma etch process on a production workpiece in a reactor chamber having a ceiling overlying a workpiece support surface, comprising:
providing an adjustable workpiece-to-ceiling gap between said workpiece support surface and said ceiling;
performing successive plasma etch processes on successive test workpieces under identical process conditions at different successive values of said gap;
measuring a post-etch critical dimension (CD) on each test workpiece and correlating each CD with the corresponding workpiece-to-ceiling gap to produce correlated measurements;
searching said correlated measurements for: (1) a first value of said gap at which measured CD features exceeds a desired CD value, and (2) a second value of said gap at which measured CD is less than said desired CD value; and
placing the production workpiece in said reactor, setting said gap to an intermediate value between said first and second values and performing an etch process while maintaining said process parameters at said same set of corresponding parameter values.

17. The method of claim 16 wherein each of said successive etch processes comprises:
flowing a process gas into said chamber at a gas flow rate;
evacuating said chamber to a chamber pressure;
coupling RF bias power to the workpiece at a bias power level;
coupling RF source power into the chamber at a source power level.

18. The method of claim 17 wherein said process conditions comprise said gas flow rate, said chamber pressure, said bias power level and said source power level, wherein said gas flow rate, said chamber pressure, said bias power level and said source power level are the same for each of said successive etch processes.

19. The method of claim 18 wherein said process conditions provide a required process performance value.

20. The method of claim 19 wherein said required performance value is a desired etch rate.
